(19) United States
(12) Patent Application Publication
(10) Pub. No.: US 2024/0088042 A1
(43) Pub. Date: Mar. 14, 2024

(54) SEMICONDUCTOR STRUCTURES AND MANUFACTURING METHOD THEREOF

(71) Applicant: TAIWAN SEMICONDUCTOR MANUFACTURING COMPANY LTD., HSINCHU (TW)

(72) Inventors: SHU-WEI LI, HSINCHU (TW); HAN-TANG HUNG, TAIPEI CITY (TW); YU-CHEN CHAN, TAICHUNG CITY (TW); CHIEN-HSIN HO, TAICHUNG CITY (TW); SHIN-YI YANG, NEW TAIPEI CITY (TW); MING-HAN LEE, TAIPEI CITY (TW); SHAU-LIN SHUE, HSINCHU (TW)

(21) Appl. No.: 18/152,778

(22) Filed: Jan. 11, 2023

Related U.S. Application Data
(60) Provisional application No. 63/374,906, filed on Sep. 8, 2022.

(51) Int. Cl. H01L 23/532; H01L 21/768; H01L 23/522

(52) U.S. Cl. CPC H01L 23/53276; H01L 21/76885; H01L 23/5226; H01L 23/53238; H01L 23/53252; H01L 23/53266; H01L 23/5329

(57) ABSTRACT

A semiconductor structure includes a dielectric layer over a substrate, a via conductor over the substrate and in the dielectric layer, and a first graphene layer disposed over the via conductor. In some embodiments, a top surface of the via conductor and a top surface of the dielectric layer are level. In some embodiments, the first graphene layer overlaps the via conductor from a top view. In some embodiments, the semiconductor structure further includes a second graphene layer under the via conductor and a third graphene layer between the dielectric layer and the via conductor. In some embodiments, the second graphene layer is between the substrate and the via conductor.

### PRIORITY CLAIM AND CROSS-REFERENCE

This application claims the benefit of prior-filed provisional application No. 63/374,906, filed on Sep. 8, 2022.

### BACKGROUND

The semiconductor integrated circuit (IC) industry has experienced rapid growth. Technological advances in IC materials and design have produced continuous improvements in generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling down process generally provides benefits by increasing production efficiency and lowering associated costs.

However, as the feature sizes continue to decrease, fabrication processes continue to become more difficult to perform. Thus, there is a challenge to form reliable semiconductor devices with smaller and smaller sizes.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a fragmentary cross-sectional view of a semiconductor structure.

FIGS. 2A to 2D are schematic drawings respectively illustrating a semiconductor structure according to various aspects of the present disclosure.

FIGS. 3A-3Q are schematic drawings respectively illustrating a semiconductor structure according to various aspects of the present disclosure.

FIG. 4 is a flowchart of a method for forming a semiconductor structure according to various aspects of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, are used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus is otherwise oriented (rotated 90 degrees or at other orientations) and the spatially relative descriptors used herein are likewise interpreted accordingly. In the present disclosure, a phrase “one of A, B and C” means “A, B and/or C” (A, B, C, A and B, A and C, B and C, or A, B and C), and does not mean one element from A, one element from B and one element from C, unless otherwise described.

As used herein, although terms such as “first,” “second” and “third” describe various elements, components, regions, layers and/or sections, these elements, components, regions, layers and/or sections are not limited by these terms. These terms are used to distinguish one element, component, region, layer, or section from another. Terms such as “first,” “second” and “third” in response to used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that is contemplated by people having ordinary skill in the art. Alternatively, the terms “substantially,” “approximately” and “about” mean within an acceptable standard error of the mean in response to considered by one of ordinary skill in the art. People having ordinary skill in the art understand that the acceptable standard error varies according to different technologies. Other than in the operating/working examples, or unless otherwise expressly specified, the numerical ranges, amounts, values, and percentages such as those for quantities of materials, durations of times, temperatures, operating conditions, ratios of amounts, and the likes thereof disclosed herein should be understood as modified in instances by the terms “substantially,” “approximately” or “about.” Accordingly, unless indicated to the contrary, the numerical parameters set forth in the present disclosure and attached claims are approximations that vary as desired. At the very least, each numerical parameter is construed considering the number of reported significant digits and by applying ordinary rounding techniques. Ranges are expressed herein as from one endpoint to another endpoint or between two endpoints. All ranges disclosed herein are inclusive of the endpoints, unless otherwise specified.

An IC manufacturing process flow can typically be divided into three categories: front-end-of-line (FEOL), middle-end-of-line (MEOL) and back-end-of-line (BEOL) processes. FEOL generally encompasses processes related to fabrication of IC devices, such as transistors. For example, FEOL processes can include forming isolation structures for isolating IC devices, gate structures, and source and drain structures (also referred to as source/drain structures) that form a transistor. MEOL generally encompasses processes related to fabrication of semiconductor structures (also referred to as contacts or plugs) that connect to conductive structures (or conductive regions) of the IC devices. For example, MEOL processes can include forming connecting structures that connect to the gate structures and connecting structures that connect to the source/drain structures. BEOL generally encompasses processes related to fabrication of multilayer interconnect (MLI) structures that electrically connect the IC devices and the connecting structures fabricated by FEOL and MEOL processes. Accordingly, operation of the IC devices can be enabled.

As mentioned above, the scaling down processes have increased the complexity of processing and manufacturing of ICs. For example, it is found that resistance of metal (for example, copper), which is used to form semiconductor structure including the connecting structures formed by MEOL and BEOL processes, is increased when a thickness of the metal is reduced.

The present disclosure therefore provides a semiconductor structure and a method for forming the same. In some embodiments, hybrid graphene/metal materials are used to form the semiconductor structure, such that the increased-resistance issue of the semiconductor structure can be mitigated while reducing the device size. In some embodiments, the semiconductor structure including the hybrid graphene/metal materials can be used to form MEOL connecting structures. For example, the semiconductor structure including the hybrid graphene/metal materials can be a MEOL metallization such as a contact or a plug. In other embodiments, the semiconductor structure including the hybrid graphene/metal materials can be used to form BEOL connecting structures. In such embodiments, the semiconductor structure including the hybrid graphene/metal materials can be a BEOL metallization such as lines that are connected to each other by vias.

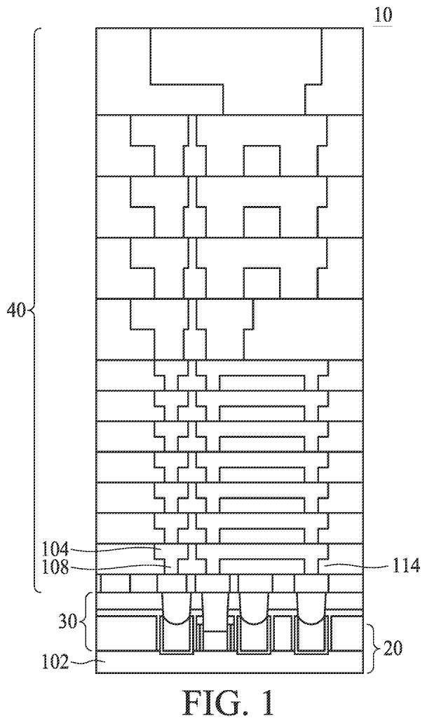

FIG. 1 is a fragmentary cross-sectional view of a semiconductor structure 10. In some embodiments, an IC manufacturing process flow can be divided into three categories: front-end-of-line (FEOL), middle-end-of-line (MEOL) and back-end-of-line (BEOL). FEOL generally encompasses processes related to fabrication of IC devices, such as transistors. For example, FEOL processes can include formation of isolation structures for isolating IC devices, gate structures, and source and drain structures (also referred to as source/drain structures) that form a transistor. In some embodiments, the devices formed by the FEOL processes can be referred to as FEOL devices 20. MEOL generally encompasses processes related to fabrication of connecting structures (also referred to as contacts or plugs) that connect to conductive structures (or conductive regions) of the IC devices. For example, MEOL processes can include formation of connecting structures that connect to the gate structures and connecting structures that connect to the source/drain structures. In some embodiments, the connecting structures formed by the MEOL processes can be referred to as MEOL structures 30. BEOL generally encompasses processes related to fabrication of multilayer interconnect (MLI) structures that electrically connect the IC devices to the connecting structures fabricated by FEOL and MEOL. In some embodiments, the MLI structures formed by the BEOL processes can be referred to as BEOL structures 40. Accordingly, a semiconductor structure 10 can be constructed by the FEOL devices 20, the MEOL structures 30 and the BEOL structures 40, and operation of the IC devices can be enabled.

As shown in FIG. 1, the semiconductor structure 10 may include a substrate (wafer) 102. In some embodiments, the substrate 102 includes silicon. Alternatively or additionally, the substrate 102 includes another elementary semiconductor, such as germanium; a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlinAs, AlGaAs, GalnAs, GaInP, and/or GaInAsP; or combinations thereof. In some implementations, the substrate 102 includes one or more group III-V materials, one or more group II-IV materials, or combinations thereof. In some implementations, the substrate 102 is a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other suitable methods. The substrate 102 can include various doped regions (not shown) configured according to design requirements of a device, such as p-type doped regions, n-type doped regions, or combinations thereof. P-type doped regions (for example, p-type wells) include p-type dopants, such as boron, indium, another p-type dopant, or combinations thereof. N-type doped regions (for example, n-type wells) include n-type dopants, such as phosphorus, arsenic, another n-type dopant, or combinations thereof. In some implementations, the substrate 102 includes doped regions formed with a combination of p-type dopants and n-type dopants. The various doped regions can be formed directly on and/or in the substrate 102, for example, providing a p-well structure, an n-well structure, a dual-well structure, a raised structure, or combinations thereof. An ion implantation process, a diffusion process, and/or another suitable doping process can be performed to form the various doped regions.

Isolations (not shown) can be formed over and/or in the substrate 102 to electrically isolate various regions, such as various device regions, of the semiconductor structure. For example, the isolations can define and electrically isolate active device regions and/or passive device regions from each other. The isolations can include silicon oxide, silicon nitride, silicon oxynitride, another suitable isolation material, or combinations thereof. Isolation features can include different structures, such as shallow trench isolation (STI) structures, deep trench isolation (DTI) structures, and/or local oxidation of silicon (LOCOS) structures.

Various devices (not shown) can be formed over the substrate 102. For example, a field effect transistor (FET) device including a gate structure, a source structure and a drain structure can be disposed over the substrate 102, though not shown. In some embodiments, the gate structure can be formed over a fin structure. In some embodiments, the gate structure can include a metal gate structure. In some embodiments, the metal gate structure includes a gate dielectric layer and a gate electrode. The gate dielectric layer can be disposed over the substrate 102, and the gate electrode is disposed on the gate dielectric layer. The gate dielectric layer includes a dielectric material, such as silicon oxide, high-k dielectric material, another suitable dielectric material, or combinations thereof. High-k dielectric material generally refers to dielectric materials having a high dielectric constant, for example, a dielectric constant greater than that of silicon oxide (k=3.9). Exemplary high-k dielectric materials include hafnium, aluminum, zirconium, lanthanum, tantalum, titanium, yttrium, oxygen, nitrogen, another suitable constituent, or combinations thereof. In some embodiments, the gate dielectric layer includes a multilayer structure, such as an interfacial layer (IL) including, for example, silicon oxide, and a high-k dielectric layer including, for example, HfO₂, HfSiO, HfSiON, HfTaO, HfSiO, HfZrO, ZrO₂, Al₂O₃, HfO₂—Al₂O₃, TiO₂, Ta₂O₅, La₂O₃, Y₂O₃, another suitable high-k dielectric material, or combinations thereof.

The gate electrode includes an electrically-conductive material. In some implementations, the gate electrode includes multiple layers, such as one or more work function metal layers and gap-filling metal layers. The work function metal layer includes a material tuned to have a desired work function (such as an n-type work function or a p-type work function), such as n-type work function materials and/or p-type work function materials. P-type work function materials include TiN, TaN, Ru, Mo, Al, WN, ZrSi₂, MoSi₂, TaSi₂, NiSi₂, WN, other p-type work function material, and combinations thereof. N-type work function materials include Ti, Al, Ag, Mn, Zr, TiAl, TiAlC, TaC, TaCN, TaSiN, TaAl, TaAlC, TiAlN, other n-type work function materials, and combinations thereof. The gap-filling metal layer can include a suitable conductive material, such as Al, W, and/or Cu.

The gate structure can further include spacers (not shown), which are disposed adjacent to (for example, along sidewalls of) the gate structure. The spacers can be formed by any suitable process and include a dielectric material. The dielectric material can include silicon, oxygen, carbon, nitrogen, another suitable material, or combinations thereof (for example, silicon oxide, silicon nitride, silicon oxynitride, or silicon carbide). In some embodiments, the spacers can include a multilayer structure, such as a first dielectric layer that includes silicon nitride and a second dielectric layer that includes silicon oxide. In some embodiments, more than one set of spacers, such as seal spacers, offset spacers, sacrificial spacers, dummy spacers, and/or main spacers, are formed adjacent to the gate structure.

Implantation, diffusion, and/or annealing processes can be performed to form lightly-doped source and drain (LDD) features and/or heavily-doped source and drain (HDD) features in the substrate 102 before and/or after the forming of the spacers.

In some embodiments, the source structure and the drain structure of the device can include epitaxial structures (not shown). Accordingly, the gate structure, the epitaxial source/drain structure and a channel region defined between the epitaxial source/drain structures form a device such as a transistor. In some embodiments, the epitaxial source/drain structures can surround source/drain regions of a fin structure. In some embodiments, the epitaxial source/drain structures can replace portions of the fin structure. The epitaxial source/drain structures are doped with n-type dopants and/or p-type dopants. In some embodiments, where the transistor is configured as an n-type device (for example, having an n-channel), the epitaxial source/drain structure can include silicon-containing epitaxial layers or silicon-carbon-containing epitaxial layers doped with phosphorous, another n-type dopant, or combinations thereof (for example, Si:P epitaxial layers or Si:C:P epitaxial layers). In alternative embodiments, where the transistor is configured as a p-type device (for example, having a p-channel), the epitaxial source/drain structures can include silicon-and-germanium-containing epitaxial layers doped with boron, another p-type dopant, or combinations thereof (for example, Si:Ge:B epitaxial layers). In some embodiments, the epitaxial source/drain structures include materials and/or dopants that achieve desired tensile stress and/or compressive stress in the channel region.

In some embodiments, a plurality of connection structures formed over the substrate 102 may be a multi-layered interconnect (MLI) structure and may include via conductors 108, conductive features 104 embedded in dielectric layers 114 (such as multiple inter-metal dielectric (IMD) layers). In some examples, each of the via conductors 108 and the conductive features 104 is embedded in a separate dielectric layer 114. In other examples, a via conductor 108 and a conductive feature 104 may be formed together in a dielectric layer 114. Conductive features at the same level may be collectively referred to as a metal layer and different metal layers are interconnected by one or more via conductors 108. The connection structure is configured to provide interconnections (e.g., wiring) between the various microelectronic components that have been or will be formed on the semiconductor structure 10. There may be intermediate layers or components disposed between the connection structure and the substrate 102, but in the interest of simplicity such layers or components are not shown. The dielectric layer 114 may include silicon oxide or a low-k dielectric material whose dielectric constants are less than that of silicon dioxide, which is within a range from about 1.5 to 3.9, but the disclosure is not limited thereto. In some embodiments, the low-k dielectric materials include a porous organosilicate thin film such as SiOCH, tetraethylorthosilicate (TEOS) oxide, un-doped silicate glass, doped silicon oxide such as borophosphosilicate glass (BPSG), fused silica glass (FSG), phosphosilicate glass (PSG), fluorine-doped silicon dioxide, carbon-doped silicon dioxide, porous silicon dioxide, porous carbon-doped silicon dioxide, silicon carbon nitride (SiCN), silicon oxycarbide (SiOCN), hydrogen silsesquioxane (HS Q), methylsilsesquioxane (MSQ), or combinations thereof. The dielectric layer 114 may further include one or more ESL disposed between the via conductors 108 and the conductive features 104 (i.e., between dielectric layers 114). The ESL may include silicon carbon nitride (SiCN), silicon oxycarbide (SiOCN), silicon oxycarbide (SiOC), silicon carbide (SiC), silicon nitride (SiN), or combinations thereof, and may be formed over the connection structure by a suitable method such as atomic layer deposition (ALD) and/or CVD.

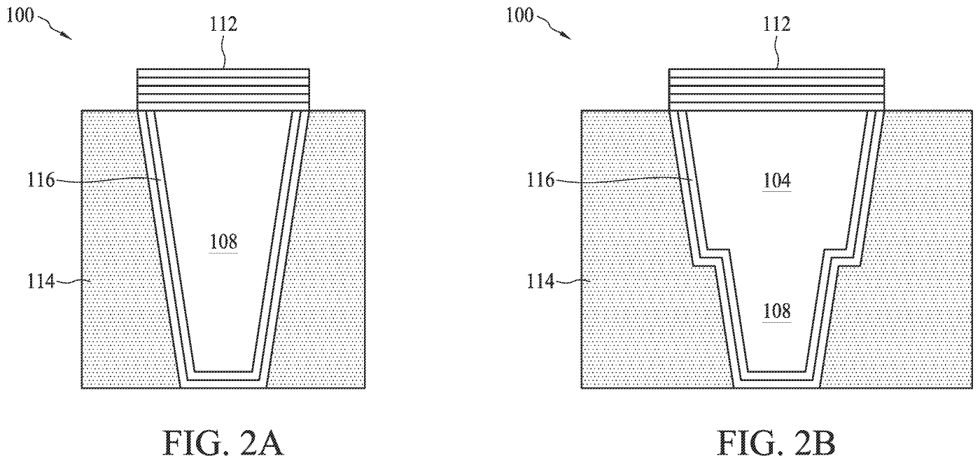

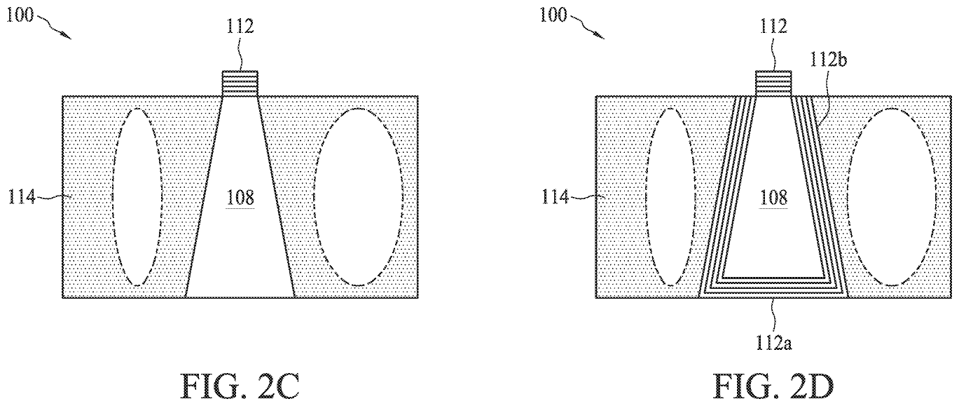

FIGS. 2A to 2D are schematic drawings respectively illustrating a semiconductor structure according to various aspects of the present disclosure. It should be noted that same elements in FIGS. 2A to 2D are indicated by the same numerals, and can include a same material. In some embodiments, a semiconductor structure 100 can be provided as shown in FIGS. 2A to 2D. In some embodiments, the via conductors 108 and conductive features 104 are formed in the dielectric layers 114. In some embodiments, the via conductor 108 and the conductive feature 104 may contact the dielectric layers 114. Each via conductor 108 and the conductive feature 104 may be formed separately by single damascene processes (as shown in FIG. 2A) and/or collectively by dual damascene processes (as shown in FIG. 2B).

In a single damascene process, a via opening for forming a via conductor 108 (or a trench for forming a conductive feature 104) is first formed in one of the dielectric layers 114, and followed by filling the via opening (or the trench) with a conductive material. A planarization process such as a chemical-mechanical polishing or planarization (CMP) process is then performed to remove the excess portions of the conductive material formed over the top surface of the dielectric layer 114, leaving the via conductor 108 (or the conductive feature 104) in the via opening (or the trench). In some embodiments, the conductive material may include cobalt (Co), bismuth (Bi), palladium (Pd), copper (Cu), nickel (Ni), ruthenium (Ru), tungsten (W), molybdenum (Mo), titanium (Ti), zirconium (Zr), tantalum (Ta), zinc (Zn), gold, other suitable metals, their respective alloys, or combinations thereof, and may be deposited by any suitable method, such as chemical vapor deposition (CVD), plating (e.g., electroplating, electroless plating, etc.) other suitable methods, or combinations thereof. In some embodiments, the conductive material includes copper in the form of, for example, elemental copper, cupronickel, a copper-aluminum alloy, other copper-containing alloys, or combinations thereof.

In a dual damascene process, a trench and a via opening are formed together in dielectric layer 114, with the via opening disposed below and connected to the trench. The conductive material is then deposited in the trench and the via opening in a single deposition process to form the conductive feature 104 over the via conductor 108 as shown in FIG. 2B. When the via opening is formed through the dielectric layer using, for example, an acceptable photolithography and etching process(es). The etching may be any acceptable etch process, such as a reactive ion etch (RIE), neutral beam etch (NBE), the like, or a combination thereof. The etch may be anisotropic. The etching may form an opening with substantially vertical sidewalls, although non-vertical sidewalls are contemplated in some embodiments.

In some embodiments, the via conductor 108 and the conductive feature 104 may be disposed over a linear or a barrier layer 116. In some embodiments, the linear or the barrier layer 116 is disposed between the dielectric layer 114 and the via conductor 108. In some embodiments, the linear or the barrier layer 116 is disposed between the dielectric layer 114 and the conductive feature 104. In some embodiments, the linear may include cobalt, ruthenium or the like. In some embodiments, the barrier layer may include titanium, titanium nitride, tantalum, tantalum nitride, tungsten, cobalt, cobalt nitride, tungsten nitride, ruthenium, ruthenium nitride, other suitable metals, other suitable metal nitrides, or combinations thereof.

After the planarization process to remove the excess portions of the conductive material formed over the top surface of the dielectric layer 114 as described above, a first graphene layer 112 may be formed over the via conductor 108 or the conductive feature 104. In some embodiments, the first graphene layer 112 may include various types such as pristine graphene, vertical graphene, intercalated graphene (horizontal/vertical), or the like. In some embodiments, an intercalated-graphene can be fabricated by CVD, electrochemical or self-diffusion process. In some embodiments, the intercalant materials can be organic materials, inorganic materials, metal complexes or metal ions. In some embodiments, the first graphene layer 112 may be deposited by a suitable method such as plasma-enhanced chemical vapor deposition (PECVD), chemical vapor deposition (CVD), the like, or any suitable method. In some embodiments, plasma sources of the PECVD depositing the first graphene layer 112 can be microwave, such as inductively coupled plasma (ICP) or capacitively coupled plasma (CCP). In some embodiments, the first graphene layer 112 can be deposited selectively on the conductive material by controlling the processes temperature, for example, about 300 degrees Celsius, but the disclosure is not limited thereto. In some embodiments, the first graphene layer 112 at the same level may be collectively referred to as a conducting layer, and different conducting layers are interconnected by one or more via conductors 108.

FIGS. 2C-2D illustrate schematic drawings when a conductor 108 is formed by using reactive ion etch (RIE) processes, in some embodiments. Referring to FIG. 2C, in such embodiments, the conductive material is formed over the substrate 102, then an etching process is performed to form the conductor 108. Subsequence to fill a dielectric material between the sidewalls of the conductor 108. A planarization process such as a chemical-mechanical polishing or planarization (CMP) process is then performed to remove the excess portions of the conductive material and the dielectric material formed over the top surface of the conductor 108. In some embodiments, a shape of the conductor 108 may be trapezoid. In some embodiments, the conductor 108 may contact the dielectric layers 114 as shown in FIG. 2C. In some embodiments, the dielectric layer 114 may include an air gap in the low-k dielectric material. In some embodiments, a ratio of the air gap and the low-k dielectric material is within a range from 1/100 to 100/1, but the disclosure is not limited thereto. The first graphene layer 112 is then deposited selectively over the conductor 108 by controlling the processes temperature, for example, about 300 degrees Celsius, but the disclosure is not limited thereto.

Referring to FIG. 2D, in such embodiments, the semiconductor structure 100 may further include a second graphene layer 112a under the conductive material, and the second graphene layer 112a is between the substrate 102 and the conductor 108. A third graphene layer 112b is between the dielectric layer 114 and the conductor 108. In this embodiments, the conductive material is formed over the substrate 102, then a second graphene layer 112a is formed under the conductive material. An etching process is performed to form the conductor 108. Then a third graphene layer 112b is formed on sidewalls of the conductor 108. The forming of the second graphene layer 112a and the third graphene layer 112b may use a transfer process to transfer a graphene material or direct growth onto the conductor 108 with the first graphene layer 112 or form afterwards. Subsequence to fill a dielectric material between the sidewalls of the conductor 108. A planarization process such as a chemical-mechanical polishing or planarization (CMP) process is then performed to remove the excess portions of the conductive material and the dielectric material formed over the top surface of the conductor 108. The first graphene layer 112 is then deposited selectively over the conductor 108 by controlling the processes temperature, for example, about 300 degrees Celsius, but the disclosure is not limited thereto.

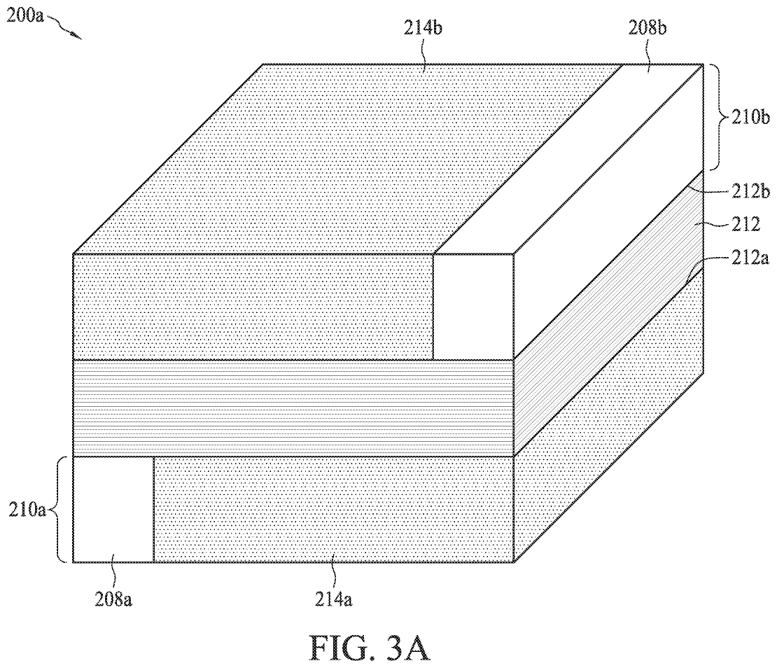

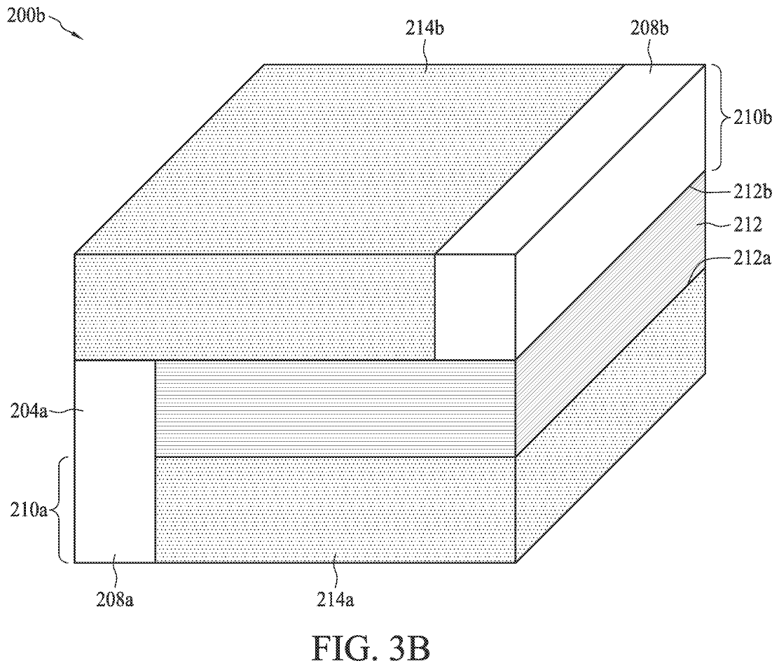

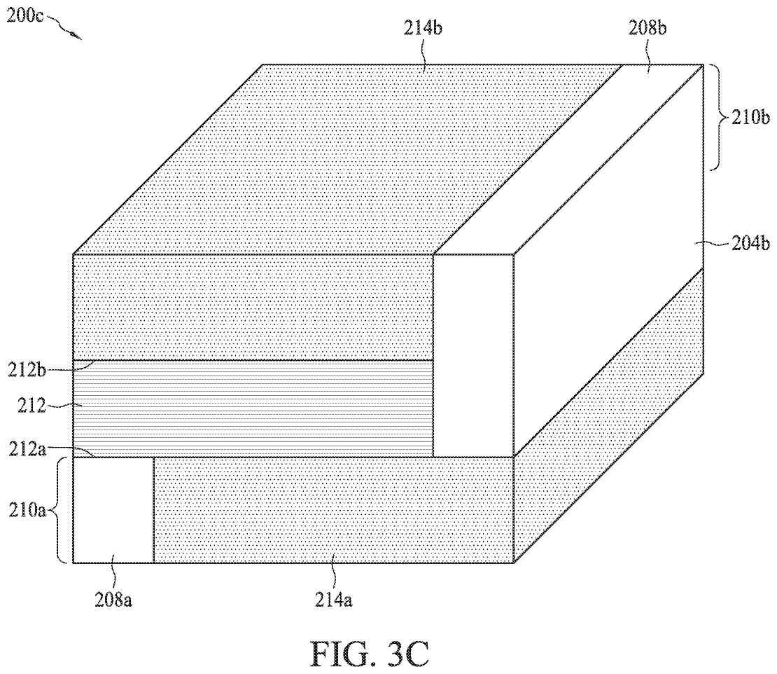

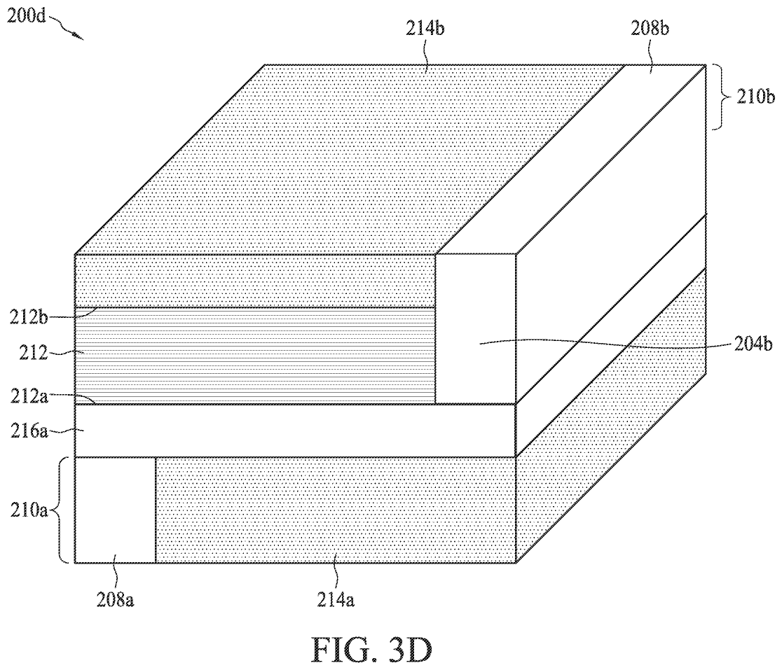

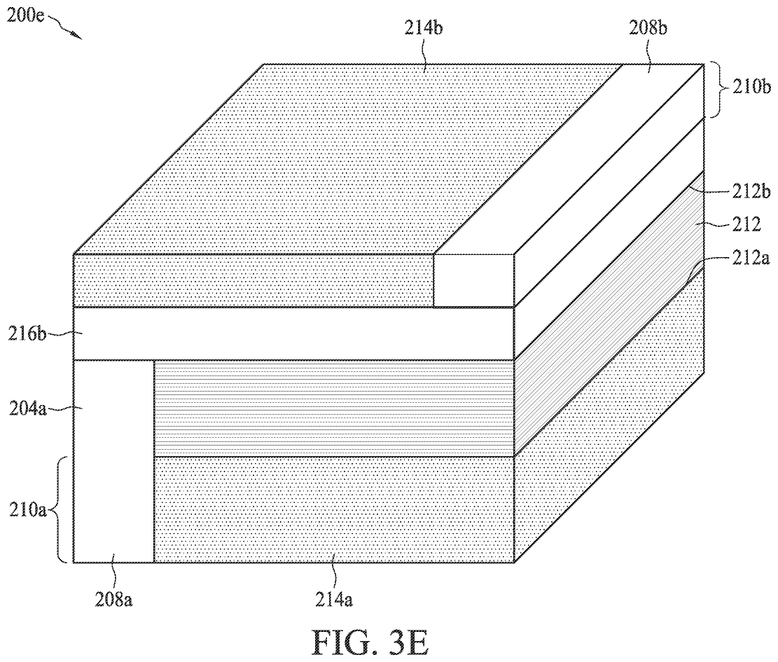

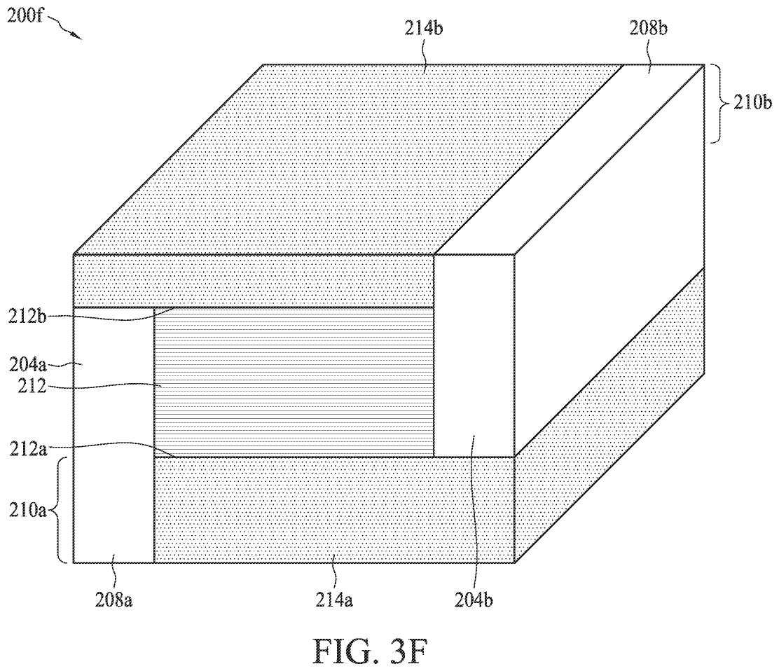

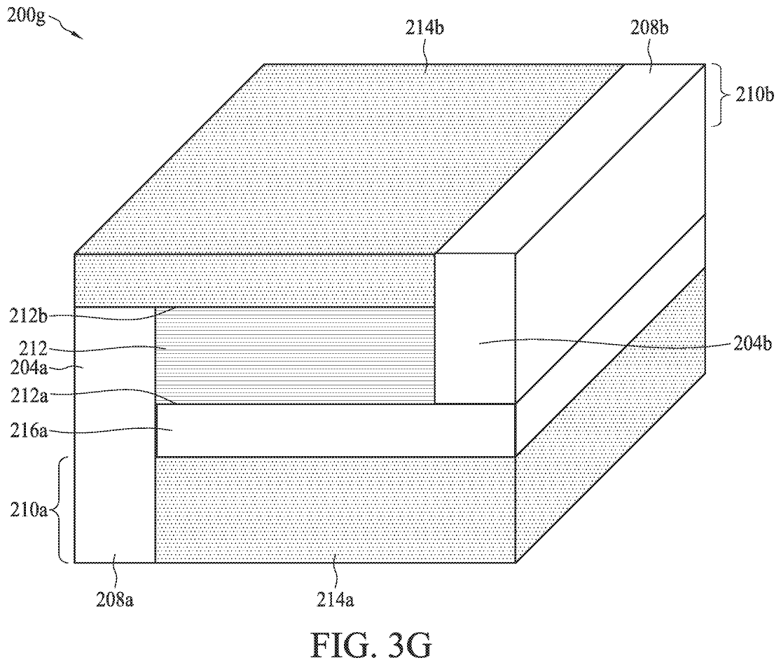

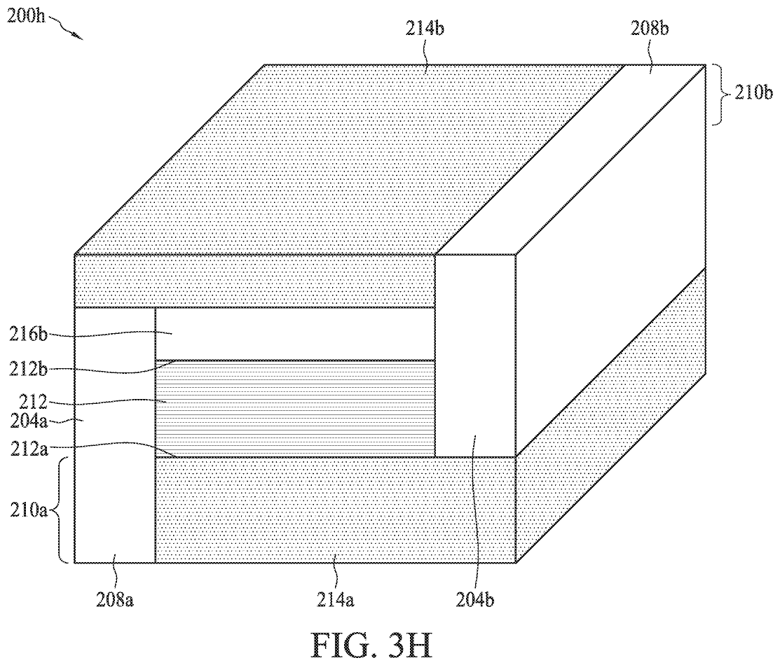

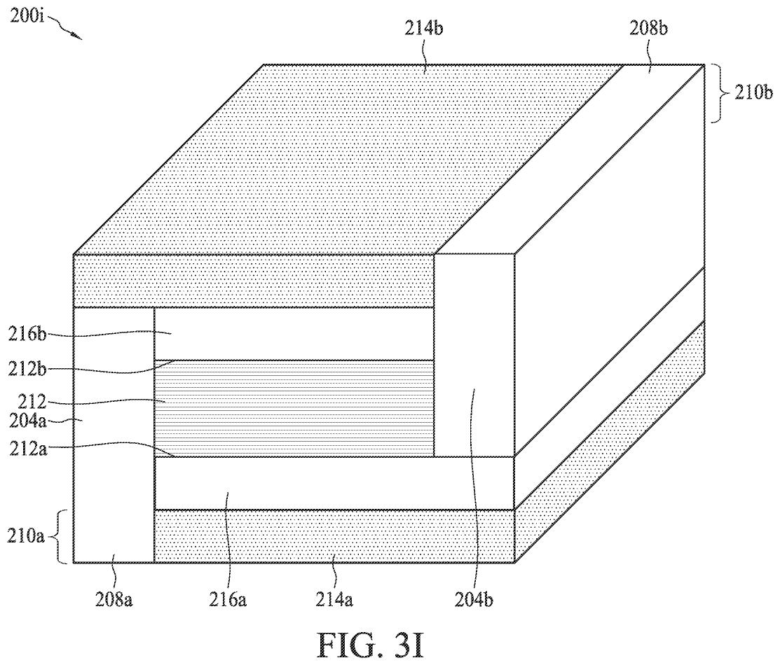

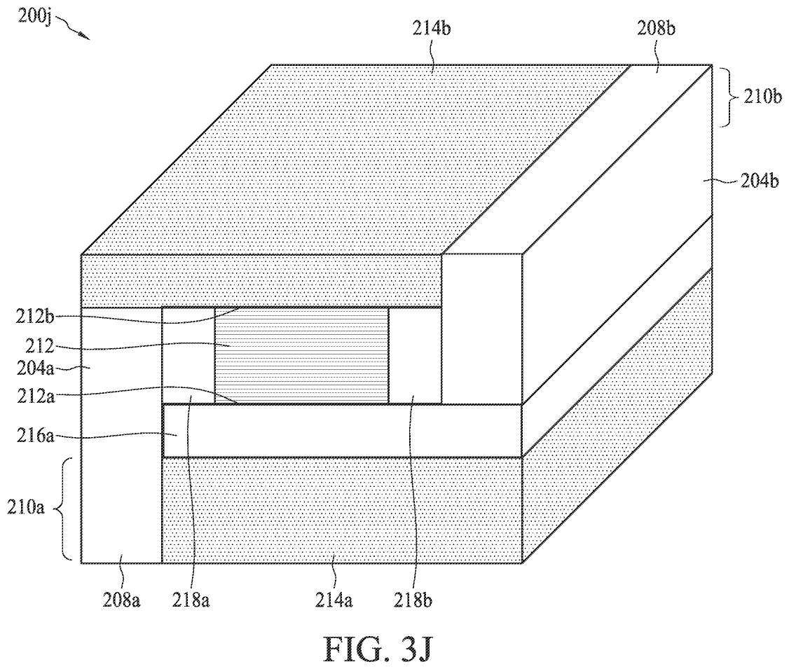

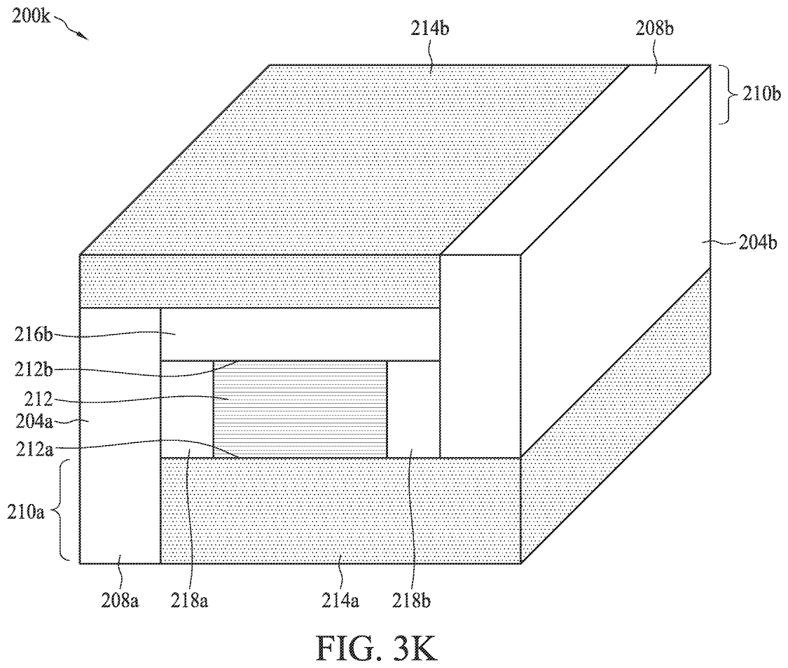

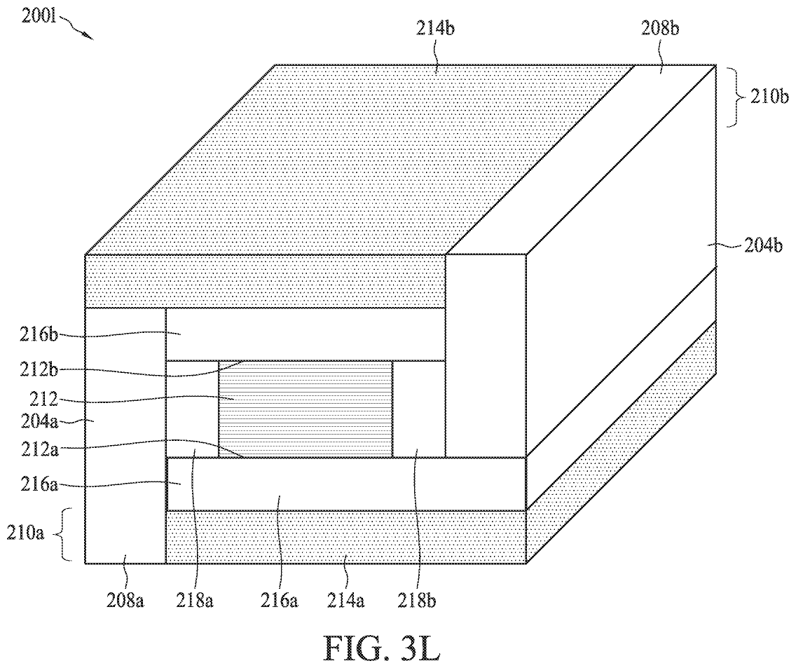

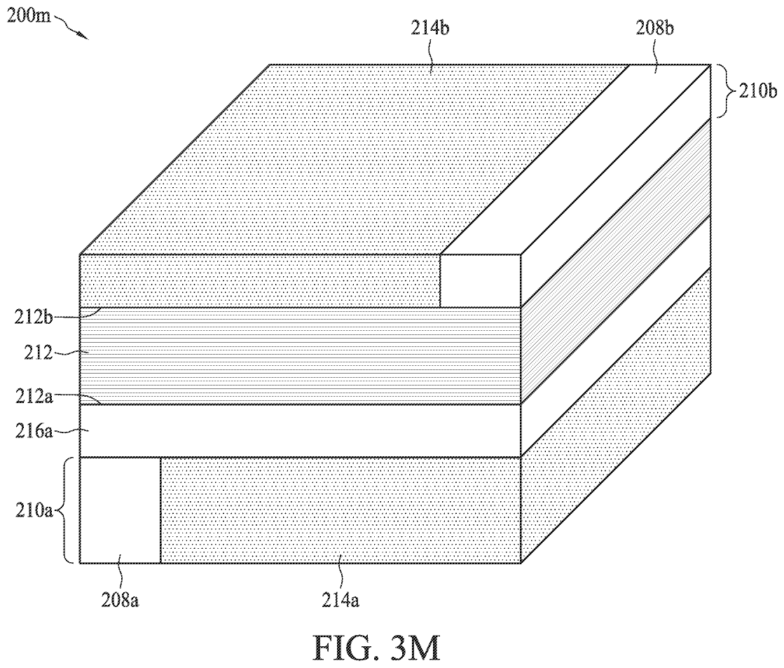

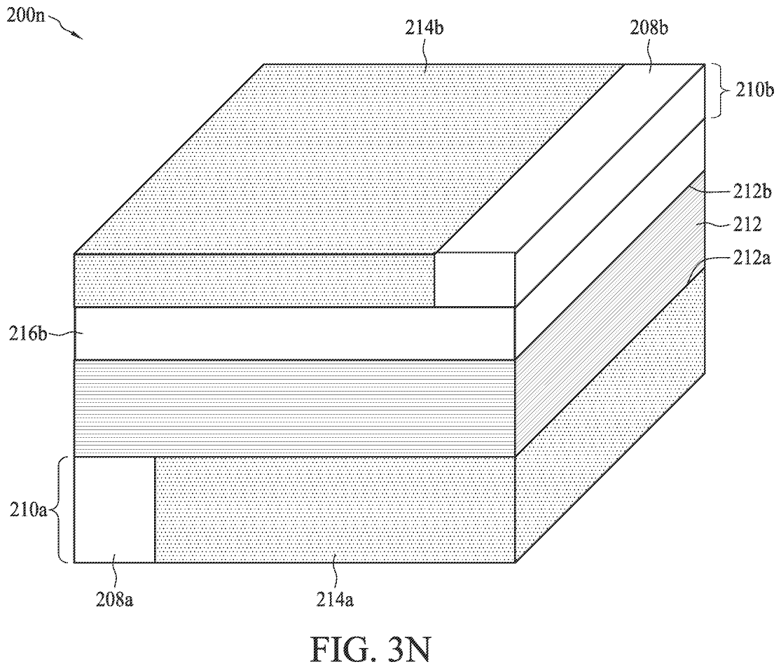

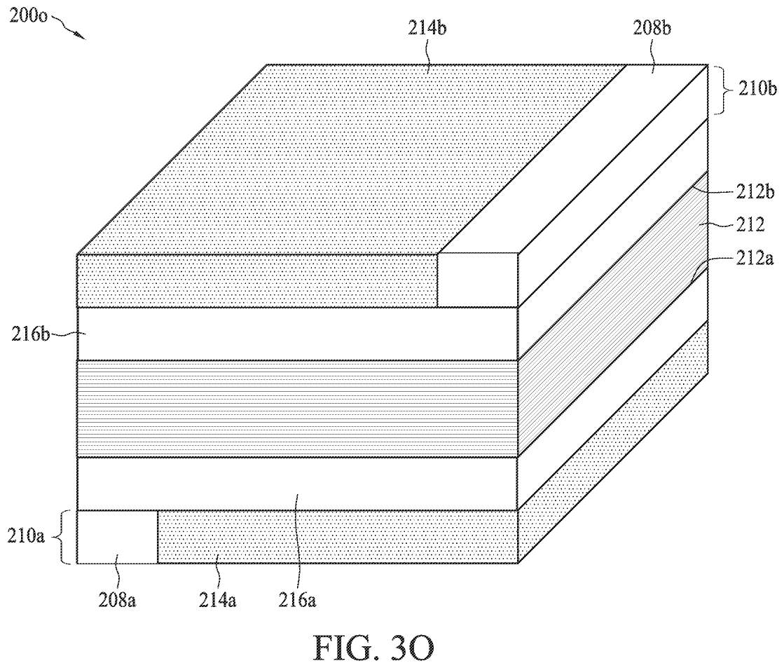

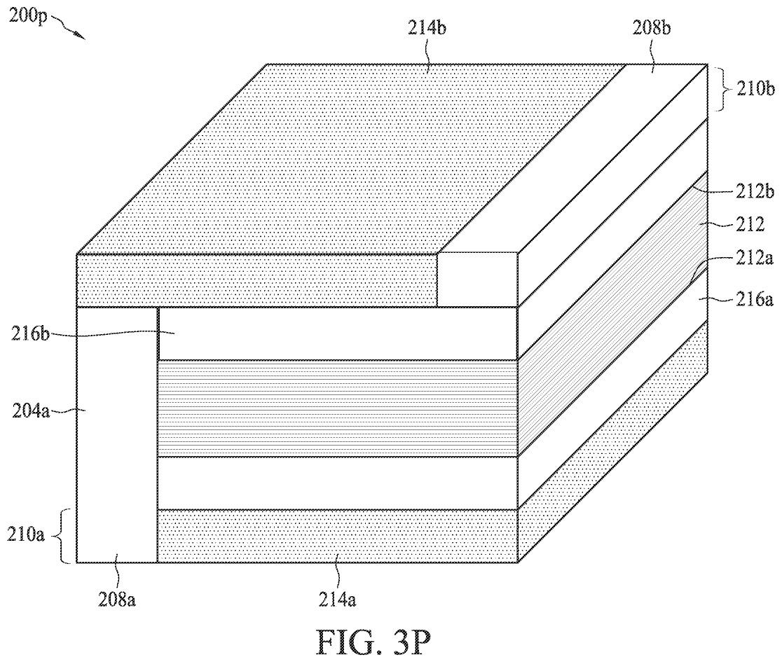

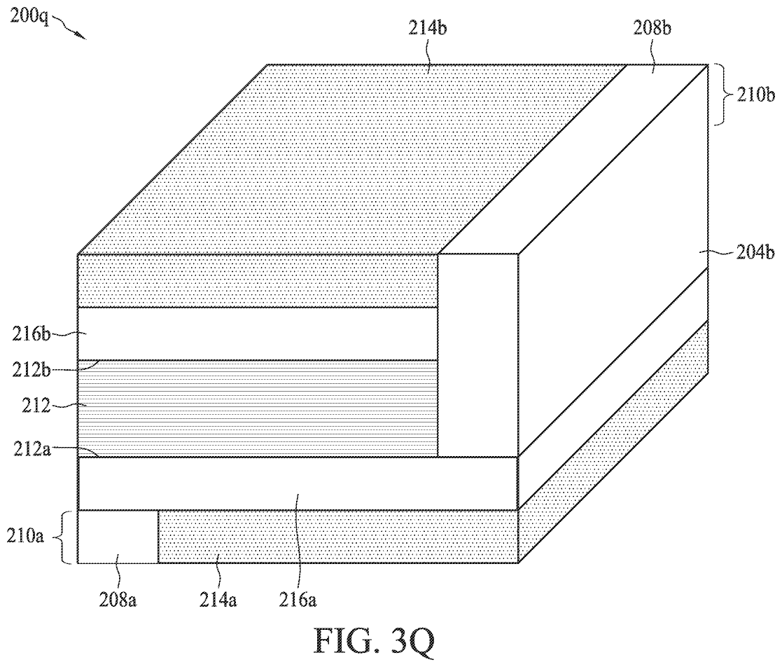

FIGS. 3A to 3Q are schematic drawings respectively illustrating a semiconductor structure according to various aspects of the present disclosure. It should be noted that same elements in FIGS. 3A to 3Q are indicated by the same numerals, and can include a same material.

In FIG. 3A, a semiconductor structure 200a over the substrate includes a first connection structure 210a, a graphene layer 212 over the first connection structure 210a, and a second connection structure 210b over the graphene layer 212. In some embodiments, the first connection structure 210a and the second connection structure 210b may be the multi-layered interconnect (MLI) structure as described above. In some embodiments, the first connection structure 210a includes a first dielectric layer 214a and a first via conductor 208a disposed in the first dielectric layer 214a. In some embodiments, the graphene layer 212 includes a first surface 212a and a second surface 212b opposite to the first surface 212a. In some embodiments, the second connection structure 210b includes a second dielectric layer 214b over the graphene layer 212 and a second via conductor 208b disposed in the second dielectric layer 214b. In some embodiments, a top surface of the first via conductor 208a is aligned and in contact with the first surface 212a of the graphene layer 212, and a bottom surface of the second via conductor 208b is aligned and in contact with the second surface 212b of the graphene layer 212. In some embodiments, the graphene layer 212 is between the first via conductor 208a and the second via conductor 208b.

In this embodiments, a via opening for forming the first via conductor 208a is first formed in the first dielectric layer 214a, and followed by filling the via opening with a conductive material. A planarization process such as a chemical-mechanical polishing or planarization (CMP) process is then performed to remove the excess portions of the conductive material formed over the top surface of the first dielectric layer 214a, leaving the first via conductor 208a in the via opening. Consequently, the first connection structure 210a is formed. In some embodiments, the conductive material may include cobalt (Co), bismuth (Bi), palladium (Pd), copper (Cu), nickel (Ni), ruthenium (Ru), tungsten (W), molybdenum (Mo), titanium (Ti), zirconium (Zr), tantalum (Ta), zinc (Zn), gold, other suitable metals, their respective alloys, or combinations thereof, and may be deposited by any suitable method, such as chemical vapor deposition (CVD), plating (e.g., electroplating, electroless plating, etc.) other suitable methods, or combinations thereof. In some embodiments, the conductive material includes copper in the form of, for example, elemental copper, cupronickel, a copper-aluminum alloy, other copper-containing alloys, or combinations thereof.

After the planarization process to remove the excess portions of the conductive material formed over the top surface of the first dielectric layer 214a, a graphene layer 212 may be formed over the first connection structure 210a. In some embodiments, the graphene layer 212 may include various types such as pristine graphene, vertical graphene, intercalated graphene (horizontal/vertical), or the like. In some embodiments, an intercalated-graphene can be fabricated by CVD, electrochemical or self-diffusion process. In some embodiments, the intercalant materials can be organic materials, inorganic materials, metal complexes or metal ions. In some embodiments, the graphene layer 212 may be deposited by a suitable method such as plasma-enhanced chemical vapor deposition (PECVD), chemical vapor deposition (CVD), a transfer process, the like, or any suitable method. In some embodiments, plasma sources of the PECVD depositing the graphene layer 212 can be microwave, inductively coupled plasma (ICP) or capacitively coupled plasma (CCP). In some embodiments, the graphene layer 212 can be deposited over the first connection structure 210a at a processes temperature over about 400 degrees Celsius, but the disclosure is not limited thereto. In some embodiments, the graphene layer 212 may be formed by adding a layer of material including cobalt, nitride or the like to facility the growth of the graphene layer 212. In some embodiments, a patterned hard mask (not shown) can be formed over the graphene layer 212, and an etching is performed to etch the graphene layer 212 through the patterned hard mask. Consequently, the graphene layer 212 is standing over the first connection structure 210a. The patterned hard mask can be removed by any suitable operation.

In some embodiments, the second connection structure 210b is formed over the graphene layer 212 by a similar process as the first connection structure 210a. Etching a via opening for forming the second via conductor 208b in the second dielectric layer 214b, and followed by filling the via opening with a conductive material. In some embodiments, a planarization process such as a CMP process is then performed to remove the excess portions of the conductive material formed over the top surface of the second dielectric layer 214b, leaving the second via conductor 208b in the via opening. Consequently, the second connection structure 210b is standing over the graphene layer 212.

FIGS. 3B to 3Q are schematic drawings respectively illustrating a semiconductor structure according to various aspects of the present disclosure. In some embodiments, the process of forming the graphene layer 212 over the hybrid material (including the conductive material and the dielectric material), such as FIGS. 3B, 3C, 3E, 3F, 3H, 3K and 3N, may be similar as the process of forming the graphene layer 212 in the semiconductor structure 200a in FIG. 3A; therefore, those details are omitted. In some embodiments, the process of forming the graphene layer 212 over the conductive material, such as FIGS. 3D, 3G, 3I, 3J, 3L, 3M, 3O, 3P and 3Q, may be similar as the process of forming the graphene layer 112 in the semiconductor structure 100 in FIG. 2B; therefore, those details are omitted. In some alternative embodiments, the graphene layer 212 disposed on the conductive material may use the transfer process to transfer the graphene material on the conductive material, similar to those process of forming the graphene layers 112a and 112b in the semiconductor structure 100 in FIG. 2B; therefore, those details are omitted.

FIG. 3B illustrates a schematic view of a semiconductor structure 200b according to some embodiments of the present disclosure. Referring to FIG. 3B, in some embodiments, the semiconductor structure 200b includes a first connection structure 210a, a graphene layer 212 over the first connection structure 210a, a first conductive feature 204a beside the graphene layer 212, and a second connection structure 210b over the graphene layer 212. In this embodiment, the first dielectric layer 214a is first formed, and followed by forming the graphene layer 212 over the first dielectric layer 214a.

After the forming of the graphene layer 212, an etching process is performed, an opening is formed in the graphene layer 212 and the first dielectric layers 214a, and followed by filling the opening with a conductive material. A portion of the conductive material filling in the first dielectric layer 214a can be referred to as the first via conductor 208a, and another portion of the conductive material over the first via conductor 208a and beside the graphene layer 212 can be referred to as the first conductive feature 204a. In some embodiments, a sidewall of the first conductive feature 204a is coupled to a sidewall of the graphene layer 212, and the first conductive feature 204a is coupled to a top surface of the first via conductor 208a. The second connection structure 210b is then formed over the graphene layer 212. In this embodiments, the forming of the second connection structure 210b is similar as the process of the second connection structure 210b in the semiconductor structure 200a in FIG. 3A as describe above.

FIG. 3C illustrates a schematic view of a semiconductor structure 200c according to some embodiments of the present disclosure. Referring to FIG. 3C, in some embodiments, the semiconductor structure 200c includes a first connection structure 210a, a graphene layer 212 over the first connection structure 210a, a second conductive feature 204b beside the graphene layer 212, and a second connection structure 210b over the graphene layer 212. In this embodiments, the forming of the first connection structure 210a is similar as the process of the first connection structure 210a in the semiconductor structure 200a in FIG. 3A as describe above. After the forming of the first connection structure 210a, the graphene layer 212 may be formed over the first connection structure 210a.

Subsequence with a deposition process for forming the second dielectric layer 214b over the graphene layer 212. In this embodiments, an opening is formed in the graphene layer 212 and the second dielectric layer 214b, and followed by filling the opening with a conductive material. A portion of the conductive material filled in the graphene layer 212 can be referred to as the second conductive feature 204b, and another portion of the conductive material over the second conductive feature 204b and in the second dielectric layer 214b can be referred to as the second via conductor 208b. In some embodiments, a sidewall of the second conductive feature 204b is coupled to a sidewall of the graphene layer 212, and the second conductive feature 204b is coupled to a bottom surface of the second via conductor 208b.

FIG. 3D illustrates a schematic view of a semiconductor structure 200d according to some embodiments of the present disclosure. Referring to FIG. 3D, in some embodiments, the semiconductor structure 200d includes a first connection structure 210a, a first conductive layer 216a over the first connection structure 210a, a graphene layer 212 over the first conductive layer 216a, a second conductive feature 204b beside the graphene layer 212, and a second connection structure 210b over the graphene layer 212. In this embodiments, a via opening for forming the first via conductor 208a is first formed in the first dielectric layer 214a, and followed by filling the via opening with a conductive material. Continue filling with the conductive material, until the conductive material fulfills the via opening and covers the first dielectric layer 214a. In some embodiments, a planarization process such as a CMP process may be performed on the top surface of the conductive material, leaving a layer over the first connection structure 210a. A portion of the conductive material filling in the first dielectric layer 214a can be referred to as the first via conductor 208a, and another portion of the conductive material over the first connection structure 210a can be referred to as a first conductive layer 216a. In some embodiments, a patterning operation may be performed to pattern the first conductive layer 216a.

Subsequence with a deposition process for forming the graphene layer 212. In some embodiments, the graphene layer 212 can be deposited selectively on the conductive material by controlling the processes temperature, for example, about 300 degrees Celsius, but the disclosure is not limited thereto. Subsequence with a deposition process for forming the second dielectric layer 214b over the graphene layer 212. In this embodiments, perform an etching process to form an opening in the graphene layer 212 and the second dielectric layer 214b, the etching process stops on the first conductive layer 216a, and then followed by filling the opening with a conductive material. A portion of the conductive material beside the graphene layer 212 can be referred to as a second conductive feature 204b, and another portion of the conductive material over the second conductive feature 204b and in the second dielectric layer 214b can be referred to as the second via conductor 208b. In some embodiments, a sidewall of the second conductive feature 204b is coupled to a sidewall of the graphene layer 212, and the second conductive feature 204b is coupled to a top surface of the first conductive layer 216a. In some embodiments, the first conductive layer 216a is under the first surface 212a of the graphene layer 212.

FIG. 3E illustrates a schematic view of a semiconductor structure 200e according to some embodiments of the present disclosure. Referring to FIG. 3E, in some embodiments, the semiconductor structure 200e includes a first connection structure 210a, a graphene layer 212 over the first connection structure 210a, a first conductive feature 204a beside the graphene layer 212, a second conductive layer 216b over the graphene layer 212, and a second connection structure 210b over the second conductive layer 216b. In this embodiment, the first dielectric layer 214a is first formed, and followed by forming the graphene layer 212 over the first dielectric layer 214a. In some embodiments, the forming of the graphene layer 212 is similar as the process of the graphene layer 212 in the semiconductor structure 200a in FIG. 3A as describe above.

After the forming of the graphene layer 212, an etching process is performed, an opening is formed in the graphene layer 212 and the first dielectric layers 214a, and followed by filling the opening with a conductive material. Continue filling with the conductive material, until the conductive material fulfills the opening and covers the graphene layer 212. In some embodiments, a planarization process such as a CMP process is then performed over the top surface of the conductive material, leaving a layer over the graphene layer 212. A portion of the conductive material filling in the first dielectric layer 214a can be referred to as the first via conductor 208a, a portion of the conductive material over the first via conductor 208a and beside the graphene layer 212 can be referred to as the first conductive feature 204a, and another portion of the conductive material over the graphene layer 212 can be referred to as the second conductive layer 216b.

Subsequence with a deposition process for forming the second dielectric layer 214b over the second conductive layer 216b. In this embodiments, the forming of the second connection structure 210b is similar as the process of the second connection structure 210b in the semiconductor structure 200a in FIG. 3A as describe above. In some embodiments, a sidewall of the first conductive feature 204a is coupled to a sidewall of the graphene layer 212, a bottom surface of the first conductive feature 204a is coupled to a top surface of the first via conductor 208a, and a top surface of first conductive feature 204a is coupled to a bottom surface of the second conductive layer 216b. In some embodiments, the second conductive layer 216b is on the second surface 212b of the graphene layer 212. Additionally, a sidewall of the second conductive layer 216b is coupled to a sidewall of the second via conductor 208b.

FIG. 3F illustrates a schematic view of a semiconductor structure 200f according to some embodiments of the present disclosure. Referring to FIG. 3F, in some embodiments, the semiconductor structure 200f includes a first connection structure 210a, a graphene layer 212 over the first connection structure 210a, a first conductive feature 204a beside the graphene layer 212, a second conductive feature 204b beside the graphene layer 212, and a second connection structure 210b over the graphene layer 212. In this embodiment, the first dielectric layer 214a is first formed, and followed by forming the graphene layer 212 over the first dielectric layer 214a. In some embodiments, the forming of the graphene layer 212 is similar as the process of the graphene layer 212 in the semiconductor structure 200a in FIG. 3A as describe above.

After the forming of the graphene layer 212, an etching process is performed, a first opening is formed in the graphene layer 212 and the first dielectric layers 214a, and followed by filling the first opening with a conductive material. A portion of the conductive material filling the first opening in the first dielectric layer 214a can be referred to as the first via conductor 208a, and another portion of the conductive material filling in the first opening in the graphene layer 212 and over the first via conductor 208a can be referred to as the first conductive feature 204a.

Subsequence with a deposition process for forming the second dielectric layer 214b over the graphene layer 212. In this embodiments, a second opening is formed in the graphene layer 212 and the second dielectric layer 214b, and followed by filling the second opening with a conductive material. A portion of the conductive material filling the second opening in in the graphene layer 212 can be referred to as the second conductive feature 204b, and another portion of the conductive material filling the second opening in the second dielectric layer 214b can be referred to as the second via conductor 208b. In some embodiments, the first conductive feature 204a is coupled to a top surface of the first via conductor 208a, and the second conductive feature 204b is coupled to a bottom surface of the second via conductor 208b. In some embodiments, a sidewall of the first conductive features 204a is coupled to one sidewall of the graphene layer 212, and a sidewall of the second conductive features 204b is coupled to another sidewall of the graphene layer 212. In some embodiments, a top surface of the first conductive feature 204a is aligned and in contact with the second surface 212b of the graphene layer 212, while a bottom surface of the second conductive feature 204b is aligned and in contact with the first surface 212a of the graphene layer 212.

FIG. 3G illustrates a schematic view of a semiconductor structure 200g according to some embodiments of the present disclosure. Referring to FIG. 3G, in some embodiments, the semiconductor structure 200g includes a first connection structure 210a, a first conductive layer 216a over the first connection structure 210a, a graphene layer 212 over the first conductive layer 216a, a first conductive feature 204a beside the graphene layer 212 and over the first conductive layer 216a, a second conductive feature 204b beside the graphene layer 212 and over the first conductive layer 216a, and a second connection structure 210b over the graphene layer 212. A first via conductor 208a is formed in the first dielectric layer 214a, and a second via conductor 208b is formed in the second dielectric layer 214b. Operations for forming the first connection structure 210a, the first conductive layer 216a, the graphene layer 212, the first and second conductive features 204a and 204b, and the second connection structure 210b are similar to those described above; therefore, those details are omitted for brevity. Further, as shown in FIG. 3G, a top surface of the first conductive feature 204a is aligned and in contact with the second surface 212b of the graphene layer 212, while a bottom surface of the second conductive feature 204b is aligned and in contact with a bottom surface of the first conductive layer 216a.

FIG. 3H illustrates a schematic view of a semiconductor structure 200h according to some embodiments of the present disclosure. Referring to FIG. 3H, in some embodiments, the semiconductor structure 200h includes a first connection structure 210a, a graphene layer 212 over the first connection structure 210a, a first conductive feature 204a beside the graphene layer 212, a second conductive feature 204b beside the graphene layer 212, a second conductive layer 216b over the graphene layer 212, and a second connection structure 210b over the second conductive layer 216b. A first via conductor 208a is formed in the first dielectric layer 214a, and a second via conductor 208b is formed in the second dielectric layer 214b. Operations for forming the first connection structure 210a, the graphene layer 212, the second conductive layer 216b, the first and second conductive features 204a and 204b, and the second connection structure 210b are similar to those described above; therefore, those details are omitted for brevity. Further, as shown in FIG. 3H, a top surface of the first conductive feature 204a is aligned and in contact with a top surface of the second conductive layer 216b, while a bottom surface of the second conductive feature 204b is aligned and in contact with the first surface 212a of the graphene layer 212.

FIG. 3I illustrates a schematic view of a semiconductor structure 200i according to some embodiments of the present disclosure. Referring to FIG. 3I, in some embodiments, the semiconductor structure 200i includes a first connection structure 210a, a first conductive layer 216a over the first connection structure 210a, a graphene layer 212 over the first conductive layer 216a, a first conductive feature 204a beside the graphene layer 212, a second conductive feature 204b beside the graphene layer 212, a second conductive layer 216b over the graphene layer 212, and a second connection structure 210b over the second conductive layer 216b. A first via conductor 208a is formed in the first dielectric layer 214a, and a second via conductor 208b is formed in the second dielectric layer 214b. Operations for forming the first connection structure 210a, the graphene layer 212, the first and second conductive layers 216a and 216b, the first and second conductive features 204a and 204b, and the second connection structure 210b are similar to those described above; therefore, those details are omitted for brevity. Further, as shown in FIG. 3I, in such embodiments, the graphene layer 212 is wrapped by the first conductive layer 216a, the second conductive layer 216b, the first conductive feature 204a and the second conductive feature 204b. In other words, sidewalls of the graphene layer 212 are in contact with a sidewall of the first conductive feature 204a and a sidewall of the second conductive feature 204b, a top surface and a bottom surface of the graphene layer 212 are in contact with a bottom surface of the second conductive feature 204b and a top surface of the first conductive layer 216a respectively.

FIG. 3J illustrates a schematic view of a semiconductor structure 200j according to some embodiments of the present disclosure. Referring to FIG. 3J, in some embodiments, the semiconductor structure 200j includes a first connection structure 210a, a first conductive layer 216a over the first connection structure 210a, a graphene layer 212 over the first conductive layer 216a, a first conductive feature 204a and a first sub conductive feature 218a beside the graphene layer 212, a second conductive feature 204b and a second sub conductive feature 218b beside the graphene layer 212, and a second connection structure 210b over the graphene layer 212. A first via conductor 208a is formed in the first dielectric layer 214a, and a second via conductor 208b is formed in the second dielectric layer 214b. Operations for forming the first connection structure 210a, the first conductive layers 216a, the graphene layer 212, the first and second conductive features 204a and 204b, and the second connection structure 210b are similar to those described above; therefore, those details are omitted for brevity. Further, as shown in FIG. 3J, in such embodiments, the first sub conductive feature 218a is coupled to a sidewall of the first conductive feature 204a, a sidewall of the graphene layer 212, and a top surface of the first conductive layer 216a. In this embodiments, the second sub conductive feature 218b is coupled to a sidewall of the second conductive feature 204b, a sidewall of the graphene layer 212, and a top surface of the first conductive layer 216a. In some embodiments, the operations for forming the first sub conductive feature 218a and the second sub conductive feature 218b may be added after the operations for forming the first conductive feature 204a. In such embodiments, a first sub opening and a second sub opening are formed in the graphene layer 212, and the first conductive layer 216a is exposed through a bottom of the first sub opening and a bottom of the second sub opening. The first sub opening and the second sub opening are then filled with a conductive material to form the first sub conductive feature 218a and the second sub conductive feature 218b. In some embodiments, a planarization process such as a CMP process is then performed to remove the excess portions of the conductive material. In this embodiments, a material of the first conductive feature 204a and a material of the first sub conductive feature 218a may be different, and a material of the second conductive feature 204b and a material of the second sub conductive feature 218b may be different, but the disclosure is not limited thereto. In this embodiments, the graphene layer 212 is in contact with a top surface of the first conductive layer 216a, a sidewall of the first sub conductive feature 218a and a sidewall of the second sub conductive feature 218b. In this embodiments, a top surface of the first conductive feature 204a, a top surface of the first sub conductive feature 218a, a top surface of the graphene layer 212, and a top surface of the second sub conductive feature 218b are aligned each other.

FIG. 3K illustrates a schematic view of a semiconductor structure 200k according to some embodiments of the present disclosure. Referring to FIG. 3K, in some embodiments, the semiconductor structure 200k includes a first connection structure 210a, a graphene layer 212 over the first connection structure 210a, a first conductive feature 204a and a first sub conductive feature 218a beside the graphene layer 212, a second conductive feature 204b and a second sub conductive feature 218b beside the graphene layer 212, a second conductive layer 216b over the graphene layer 212, and a second connection structure 210b over the second conductive layer 216b. A first via conductor 208a is formed in the first dielectric layer 214a, and a second via conductor 208b is formed in the second dielectric layer 214b. As shown in FIG. 3K, in such embodiments, the first sub conductive feature 218a is coupled to a sidewall of the first conductive feature 204a, a sidewall of the graphene layer 212, and a bottom surface of the second conductive layer 216b. In this embodiments, the second sub conductive feature 218b is coupled to a sidewall of the second conductive feature 204b, a sidewall of the graphene layer 212, and the bottom surface of the second conductive layer 216b. In this embodiments, a material of the first conductive feature 204a and a material of the first sub conductive feature 218a may be different, and a material of the second conductive feature 204b and a material of the second sub conductive feature 218b may be different, but the disclosure is not limited thereto. In this embodiments, the graphene layer 212 is in contact with a bottom surface of the second conductive layer 216b, a sidewall of the first sub conductive feature 218a and a sidewall of the second sub conductive feature 218b. In this embodiments, a bottom surface of the first sub conductive feature 218a, a bottom surface of the graphene layer 212, a bottom surface of the second sub conductive feature 218b, and a bottom surface of the second conductive feature 204b are aligned each other.

FIG. 3L illustrates a schematic view of a semiconductor structure 200l according to some embodiments of the present disclosure. Referring to FIG. 3L, in some embodiments, the semiconductor structure 200l includes a first connection structure 210a, a first conductive layer 216a over the first connection structure 210a, a graphene layer 212 over the first conductive layer 216a, a first conductive feature 204a and a first sub conductive feature 218a beside the graphene layer 212, a second conductive feature 204b and a second sub conductive feature 218b beside the graphene layer 212, a second conductive layer 216b over the graphene layer 212, and a second connection structure 210b over the second conductive layer 216b. A first via conductor 208a is formed in the first dielectric layer 214a, and a second via conductor 208b is formed in the second dielectric layer 214b. As shown in FIG. 3L, in such embodiments, a first sub conductive feature 218a is coupled to a sidewall of the first conductive feature 204a, a sidewall of the graphene layer 212, a top surface of the first conductive layer 216a, and a bottom surface of the second conductive layer 216b. In this embodiments, the graphene layer 212 is wrapped by the first conductive layer 216a, the second conductive layer 216b, the first sub conductive feature 218a and the second sub conductive feature 218b.

FIG. 3M illustrates a schematic view of a semiconductor structure 200m according to some embodiments of the present disclosure. Referring to FIG. 3M, in some embodiments, the semiconductor structure 200m includes a first connection structure 210a, a first conductive layer 216a over the first connection structure 210a, a graphene layer 212 over the first conductive layer 216a, and a second connection structure 210b over the graphene layer 212. A first via conductor 208a is formed in the first dielectric layer 214a, and a second via conductor 208b is formed in the second dielectric layer 214b. Operations for forming the first connection structure 210a, the graphene layer 212, the first conductive layers 216a, and the second connection structure 210b are similar to those described above; therefore, those details are omitted for brevity. Further, as shown in FIG. 3M in such embodiments, the graphene layer 212 is coupled to a top surface of the first conductive layer 216a and a bottom surface of the second via conductor 208b.

FIG. 3N illustrates a schematic view of a semiconductor structure 200n according to some embodiments of the present disclosure. Referring to FIG. 3N, in some embodiments, the semiconductor structure 200n includes a first connection structure 210a, a graphene layer 212 over the first connection structure 210a, a second conductive layer 216b over the graphene layer 212, and a second connection structure 210b over the second conductive layer 216b. A first via conductor 208a is formed in the first dielectric layer 214a, and a second via conductor 208b is formed in the second dielectric layer 214b. Operations for forming the first connection structure 210a, the graphene layer 212, the second conductive layers 216b, and the second connection structure 210b are similar to those described above; therefore, those details are omitted for brevity. Further, as shown in FIG. 3N in such embodiments, the graphene layer 212 is coupled to a bottom surface of the second conductive layer 216b and a top surface of the first via conductor 208a.

FIG. 3O illustrates a schematic view of a semiconductor structure 200o according to some embodiments of the present disclosure. Referring to FIG. 3O, in some embodiments, the semiconductor structure 200o includes a first connection structure 210a, a first conductive layer 216a over the first connection structure 210a, a graphene layer 212 over the first conductive layer 216a, a second conductive layer 216b over the graphene layer 212, and a second connection structure 210b over the second conductive layer 216b. A first via conductor 208a is formed in the first dielectric layer 214a, and a second via conductor 208b is formed in the second dielectric layer 214b. Operations for forming the first connection structure 210a, the graphene layer 212, the first and the second conductive layers 216a and 216b, and the second connection structure 210b are similar to those described above; therefore, those details are omitted for brevity. Further, as shown in FIG. 3O in such embodiments, the graphene layer 212 is sandwiched between a top surface of the first conductive layer 216a and a bottom surface of the second conductive layer 216b.

FIG. 3P illustrates a schematic view of a semiconductor structure 200p according to some embodiments of the present disclosure. Referring to FIG. 3P, in some embodiments, the semiconductor structure 200p includes a first connection structure 210a, a first conductive layer 216a over the first connection structure 210a, a graphene layer 212 over the first conductive layer 216a, a first conductive feature 204a beside the graphene layer 212, a second conductive layer 216b over the graphene layer 212, and a second connection structure 210b over the second conductive layer 216b. A first via conductor 208a is formed in the first dielectric layer 214a, and a second via conductor 208b is formed in the second dielectric layer 214b. Operations for forming the first connection structure 210a, the graphene layer 212, the first conductive feature 204a, the first and the second conductive layers 216a and 216b, and the second connection structure 210b are similar to those described above; therefore, those details are omitted for brevity. Further, as shown in FIG. 3P in such embodiments, the graphene layer 212 is coupled to a top surface of the first conductive layer 216a, a bottom surface of the second conductive layer 216b, and a sidewall of the first conductive feature 204a.

FIG. 3Q illustrates a schematic view of a semiconductor structure 200q according to some embodiments of the present disclosure. Referring to FIG. 3Q, in some embodiments, the semiconductor structure 200q includes a first connection structure 210a, a first conductive layer 216a over the first connection structure 210a, a graphene layer 212 over the first conductive layer 216a, a second conductive feature 204b beside the graphene layer 212, a second conductive layer 216b over the graphene layer 212, and a second connection structure 210b over the second conductive layer 216b. A first via conductor 208a is formed in the first dielectric layer 214a, and a second via conductor 208b is formed in the second dielectric layer 214b. Operations for forming the first connection structure 210a, the graphene layer 212, the second conductive feature 204b, the first and the second conductive layers 216a and 216b, and the second connection structure 210b are similar to those described above; therefore, those details are omitted for brevity. Further, as shown in FIG. 3Q in such embodiments, the graphene layer 212 is coupled to a top surface of the first conductive layer 216a, a bottom surface of the second conductive layer 216b, and a sidewall of the second conductive feature 204b.

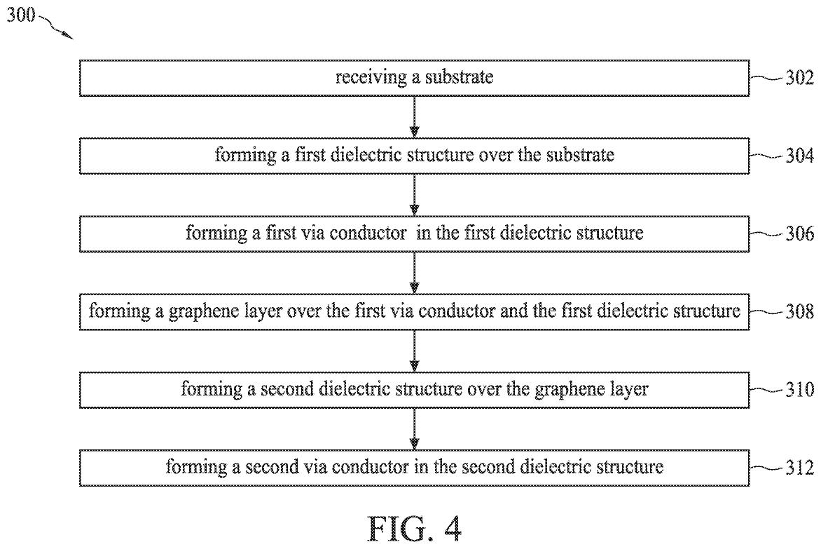

FIG. 4 is a flowchart of a method 300 for making a semiconductor structure 200a configured to receiving a substrate 102, forming a first dielectric layer 214a over the substrate 102, forming a first via conductor 208a in the first dielectric layer 214a, forming a graphene layer 212 over the first via conductor 208a and the first dielectric layer 214a, forming a second dielectric layer 214b over the graphene layer 212 and forming a second via conductor 208b in the second dielectric layer 214b. In some embodiments, the first via conductor 208a and the second via conductor 208b are opposite to each other. Referring first to block 302, the block 302 receives (or is provided with) the substrate 102. Referring to block 304, the first dielectric layer 214a may be deposited over the substrate 102 by any suitable method. Referring to block 306, the first via conductor 208a is formed in the first dielectric layer 214a by first forming a first via opening in the first dielectric layer 214a, and then followed by filling the conductive material in the first via opening. Referring to block 308, the graphene layer 212 is formed over the first via conductor 208a and the first dielectric layer 214a by any suitable method, such as PECVD, CVD, a transfer process, the like, or any suitable method. Referring to block 310, the second dielectric layer 214b may be deposited over the graphene layer 212 by any suitable method. Referring to block 312, the second via conductor 208b is formed in the second dielectric layer 214b by first forming a second via opening in the first dielectric layer 214a, and then followed by filling the conductive material in the second via opening. The more detail processes may refer to the processes of the semiconductor structure 200a in FIG. 3A. Additional steps can be provided before, during, and after the method 300, and some of the steps described can be replaced or eliminated for other embodiments of the methods 300.

In some embodiments, the present disclosure provides a semiconductor structure and a method for forming the same. In some embodiments, the hybrid graphene/metal materials are used to form the semiconductor structure, such that the increased-resistance issue of the semiconductor structure can be mitigated while reducing the device size. In some embodiments, the semiconductor structure including the hybrid graphene/metal materials can be used to form BEOL connecting structures. In such embodiments, the semiconductor structure including the hybrid graphene/metal materials can be a BEOL metallization such as lines that are connected to each other by vias.

As described in greater detail above, some implementations described herein provide a semiconductor structure including a dielectric layer over a substrate, a via conductor over the substrate and in the dielectric layer and a first graphene layer disposed over the via conductor. In some embodiments, a top surface of the via conductor and a top surface of the dielectric layer are level. In some embodiments, the first graphene layer overlaps the via conductor from a top view.

As described in greater detail above, some implementations described herein provide a semiconductor structure including a first connection structure over a substrate, a graphene layer disposed over the first connection structure, and a second connection structure over the graphene layer. In some embodiments, the first connection structure includes a first dielectric layer over the substrate and a first via conductor disposed in the first dielectric layer. In some embodiments, the graphene layer includes a first surface and a second surface opposite to the first surface. In some embodiments, the second connection structure includes a second dielectric layer over the graphene layer and a second via conductor in the second dielectric layer. In some embodiments, a top surface of the first via conductor is aligned with the first surface of the graphene layer, and a bottom surface of the second via conductor is aligned with the second surface of the graphene layer. In some embodiments, the graphene layer is between the first via conductor and the second via conductor.

As described in greater detail above, some implementations described herein provide a method including receiving a substrate, forming a first dielectric layer over the substrate, forming a first via conductor in the first dielectric layer, forming a graphene layer over the first via conductor and the first dielectric layer, forming a second dielectric layer over the graphene layer and forming a second via conductor in the second dielectric layer. In some embodiments, the first via conductor and the second via conductor are opposite to each other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a dielectric layer over a substrate;
a via conductor over the substrate and in the dielectric layer, wherein a top surface of the via conductor and a top surface of the dielectric layer are level; and
a first graphene layer disposed over the via conductor, wherein the first graphene layer overlaps the via conductor from a top view.

2. The semiconductor structure of claim 1, the via conductor further comprises a conductive feature disposed over the via conductor.

3. The semiconductor structure of claim 2, wherein the via conductor and the conductive feature have a same metal material.

4. The semiconductor structure of claim 1, further comprising:
a second graphene layer under the via conductor, wherein the second graphene layer is between the substrate and the via conductor; and
a third graphene layer between the dielectric layer and the via conductor.

5. The semiconductor structure of claim 1, wherein the dielectric layer comprises a low-k dielectric material and/or an air gap.

6. The semiconductor structure of claim 5, wherein a ratio of the air gap and the low-k dielectric material is within a range from 1/100 to 100/1.

7. The semiconductor structure of claim 1, further comprising a barrier layer disposed between the dielectric layer and the via conductor, and between the substrate and the via conductor.

8. A semiconductor structure, comprising:
a first connection structure over a substrate, comprising:
a first dielectric layer over the substrate; and
a first via conductor disposed in the first dielectric layer;
a graphene layer disposed over the first connection structure, comprising
a first surface; and
a second surface opposite to the first surface; and
a second connection structure over the graphene layer, comprising:
a second dielectric layer over the graphene layer; and
a second via conductor in the second dielectric layer,
wherein a top surface of the first via conductor is aligned with the first surface of the graphene layer, and a bottom surface of the second via conductor is aligned with the second surface of the graphene layer, and wherein the graphene layer is between the first via conductor and the second via conductor.

9. The semiconductor structure of claim 8, further comprising a conductive feature disposed over the first connection structure, wherein a sidewall of the conductive feature is coupled to a sidewall of the graphene layer, and the conductive feature is coupled to a top surface of the first via conductor or coupled to a bottom surface of the second via conductor.

10. The semiconductor structure of claim 9, further comprising a conductive layer coupled to the conductive feature, wherein the conductive layer is under the first surface of the graphene layer or on the second surface of the graphene layer.

11. The semiconductor structure of claim 8, further comprising:
a first conductive feature disposed on and coupled to a top surface of the first via conductor; and
a second conductive feature disposed on and coupled to a bottom surface of the second via conductor,
wherein a sidewall of the first conductive features is coupled to one sidewall of the graphene layer, and a sidewall of the second conductive features is coupled to another sidewall of the graphene layer.

12. The semiconductor structure of claim 11, further comprising a conductive layer coupled to the first conductive feature and the second conductive feature, wherein the conductive layer is under the first surface of the graphene layer or on the second surface of the graphene layer.

13. The semiconductor structure of claim 12, further comprising a second conductive layer and a first conductive layer coupled to the first conductive feature and the second conductive feature, wherein the first conductive layer and the second conductive layer are respectively disposed on first surface and the second surface of the graphene layer.

14. The semiconductor structure of claim 8, further comprising a first conductive layer underlies the graphene layer and is coupled to the top surface of the first via conductor.

15. The semiconductor structure of claim 14, further comprising a second conductive layer overlays the graphene layer and is couple to the bottom surface of the second via conductor.

16. The semiconductor structure of claim 15, further comprising a conductive feature disposed over the first connection structure, wherein a sidewall of the conductive feature is coupled to a sidewall of the graphene layer, a top surface of the first conductive layer and a bottom surface of the second conductive layer.

17. A method for forming a semiconductor structure, comprising:
receiving a substrate;
forming a first dielectric layer over the substrate;
forming a first via conductor in the first dielectric layer;
forming a graphene layer over the first via conductor and the first dielectric layer;
forming a second dielectric layer over the graphene layer; and
forming a second via conductor in the second dielectric layer, wherein the first via conductor and the second via conductor are opposite to each other.

18. The method of claim 17, wherein a process temperature of depositing the graphene layer is greater than about 400 degrees Celsius.

19. The method of claim 17, wherein the forming of the graphene layer further comprises:
forming a first conductive features in one side of the graphene layer over the first via conductor; and
forming a second conductive features in another side of the graphene layer, where the second via conductor is over the second conductive features.

20. The method of claim 17, wherein the forming of the first via conductor in the first dielectric layer further comprises:
forming a first conductive layer over the first via conductor and the first dielectric layer; and
forming the graphene layer over the first conductive layer, wherein a process temperature of depositing the graphene layer is about 300 degrees Celsius.
